(19) United States
(12) Patent Application Publication
(10) Pub. No.: US 2003/0071266 A1
(43) Pub. Date: Apr. 17, 2003

(54) Light emitting device and method of manufacturing the same

(76) Inventor: Wen-Chieh Huang, Taipei (TW)

Correspondence Address: BIRCH STEWART KOLASCH & BIRCH, PO BOX 747, FALLS CHURCH, VA, 22040-0747, US

(21) Appl. No.: 10/023,690

(22) Filed: Dec. 21, 2001

(30) Foreign Application Priority Data
Oct. 17, 2001 (TW) 90125664

(51) Int. Cl. H01L 27/15

(52) U.S. Cl. 257/82

(57) ABSTRACT

The invention provides a light emitting device with uniform light emission, wherein the light emitting device comprises an alloyed film formed on the p-type semiconductor layer. The alloyed film has a structure of long-range order superlattice, and is formed by annealing a multi-metal layer. The alloyed film has superior thermal conductivity and superior electrical conductivity. Thus, the current is uniformly applied to the entire p-type semiconductor layer, and the light emitting device emits uniform light.

### BACKGROUND OF THE INVENTION

1. Field of the Invention

The invention relates to a light emitting device, and more particularly to a light emitting device having an alloyed Eilm with a structure of long-range order between a p-type cladding layer and a p-electrode pad.

2. Description of the Related Art

FIG. 1 schematically shows a III-V Group compound semiconductor light-emitting device. The light-emitting device (LED) 1 has a transparent, electrically insulating substrate 2, such as sapphire. A layer 3 of an n-type gallium nitride-based III-V Group compound semiconductor is formed on a first major surface 2a of the substrate 2. Then, a layer 3 of a p-type gallium nitride-based III-V Group compound semiconductor is formed on the surface of the n-type semiconductor layer 3. Next, the p-type semiconductor layer 4 is partially etched, partially exposing the surface of the n-type semiconductor 3. An n-electrode pad 5 and p-electrode film 6 are directly formed on the surface of the n-type semiconductor layer 3 and the p-type semiconductor layer 4, respectively; and then a p-electrode pad 20 is formed on the p-electrode film 6. In order to obtain uniform light emission from the device, the p-electrode film 6 is usually formed to cover substantially the entire surface of the p-type compound semiconductor layer 4 to ensure the uniform application of current to the entire p-type compound semiconductor layer 4.

However, since the light-transmission of the p-electrode pad is not good, the light-emission efficiency of the semiconductor device is low. Most light emitted from the light emitting device 1 is observed on the side of the substrate 2; opposite to the side on which the compound semiconductor layers are formed. In the prior art, excessive heat is another problem with light emitting devices. Therefore, forming a film on the p-type semiconductor layer with the properties of transparency, good thermal conductivity, and good electrical conductivity, is an important aim of the invention.

### SUMMARY OF THE INVENTION

To solve the above problems, it is an object of the present invention to provide a light emitting device with an alloyed film with a structure of long-range order between the p-type semiconductor layer and the p-electrode pad. Further, the alloyed film is transparent and has the characteristics of superior thermal and electrical conductivity.

The present invention provides a light emitting device, including: an insulating substrate; a semiconductor including an n-type III-V Group compound semiconductor layer and a p-type III-V Group compound semiconductor layer formed on the substrate; an n-electrode pad formed on the n-type III-V Group compound semiconductor layer; and an alloyed film with a structure of long-range order formed on the p-type III-V Group compound semiconductor layer. The alloyed film is produced by annealing a multi-metal layer to form the structure of long-range order superlattice.

The invention has one advantage of superior thermal conductivity resulting from the light emitting device having an alloyed film having a structure of long-range order.

The invention has another advantage of superior electronic conductivity as a result of the same characteristics. The alloyed film also increases the electric static discharge (ESD) value of the light emitting device.

### BRIEF DESCRIPTION OF THE DRAWINGS

This and other objects and features of the invention will become clear from the following description, taken in conjunction with the preferred embodiments with reference to the drawings, in which:

FIG. 1 schematically shows a III-V Group compound semiconductor light-emitting device;

FIG. 2 is a schematic view showing a light emitting device before the annealing process in the embodiment of the present invention;

FIG. 3 schematically shows a phase diagram of Cu-Au system;

FIG. 4 is a schematic view showing a light emitting device after the annealing process in the embodiment of the present invention;

FIG. 5 schematically shows a light emitting chip mounted on a cup-like lead frame;

FIG. 6 schematically shows a light emitting device having an active layer.

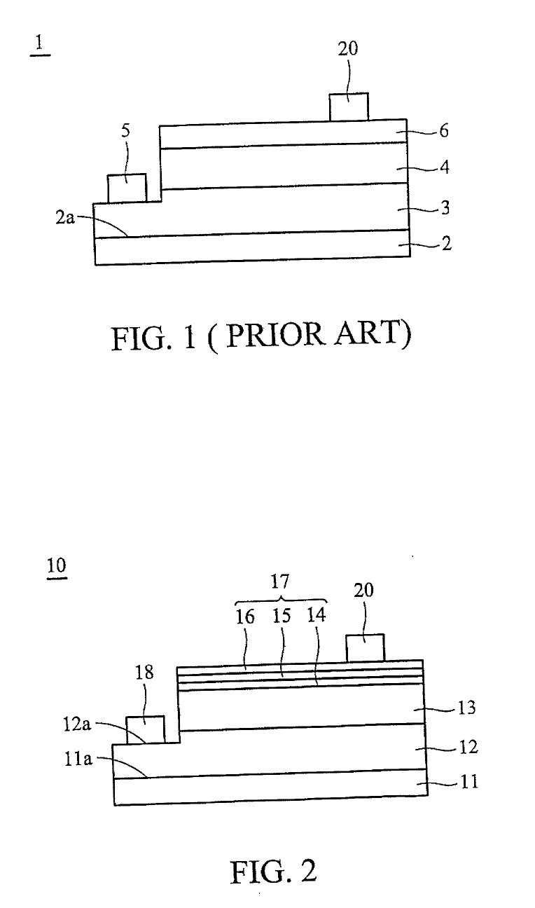

### DETAILED DESCRIPTION OF THE PREFERRED EMBODIMENTS

FIG. 2 is a schematic view showing a light emitting device before the annealing process in the embodiment of the present invention.

As shown in FIG. 2, the light-emitting device (LED) 10 has a transparent and electrically insulating substrate 11, such as sapphire. A layer 12 of an n-type gallium nitride-based III-V Group compound semiconductor is formed to a thickness of, for example, 0.5 μm to 10 μm, on a first major surface 11a of the substrate 11. The n-type semiconductor layer 12 can be doped with an n-type dopant, such as silicon (Si), germanium (Ge), selenium (Se), sulfur (S), or tellurium (Te), although the result may not be completely effective.

On the surface of the n-type semiconductor layer 12, a layer 13 of a p-type gallium nitride-based III-V Group compound semiconductor is formed to a thickness of, for example, 0.01 μm to 5 μm. The p-type semiconductor layer 13 is doped with a p-type dopant, such as beryllium (Be), strontium (Sr), barium (Ba), zinc (Zn) or magnesium (Mg).

The p-type semiconductor layer 13 is partially etched, together with a surface portion of the n-type semiconductor layer, to partially expose the surface of the n-type semiconductor layer 12. An n-electrode pad 14 is formed on the exposed surface portion 12a of the n-type semiconductor layer 12.

A multi-metal layer 17 is formed to directly cover substantially the entire surface of the p-type semiconductor layer 13. The multi-metal layer 17 includes a nickel layer 14 and two metals selected from the group consisting of CuAu, CoPt, MgCd, CuPt, TaAu and CuTi. In the embodiment of the present invention, a multi-metal layer 17 with a sequence of Ni 11, Cu 15 and Au 16 is formed upon the p-type semiconductor layer 13.

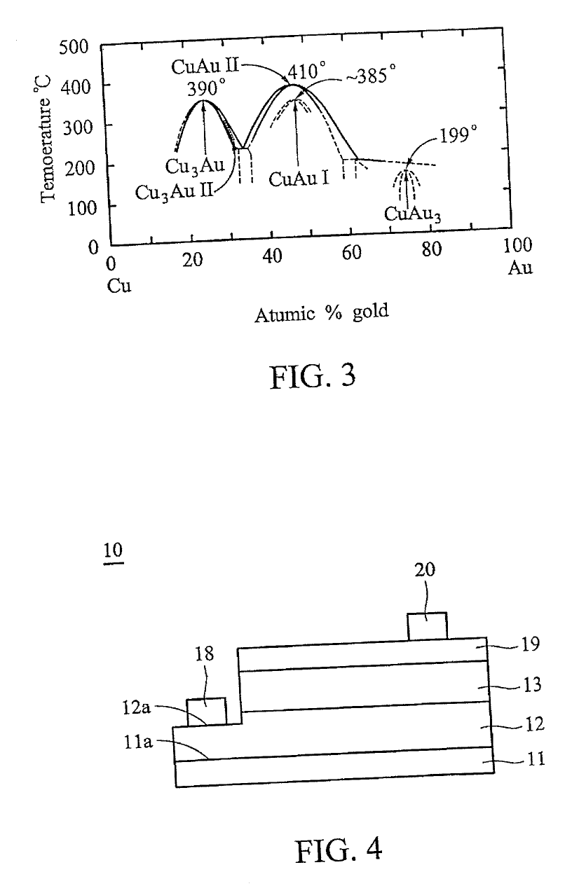

FIG. 3 schematically shows a phase diagram of Cu-Au system. As shown in FIG. 3, the arrows indicate the maximum temperature of long-range order. Thus, the multi-metal layer is annealed at a temperature of 150° C. or more.

FIG. 4 is a schematic view showing a light emitting device 10 after the annealing process in the embodiment of the present invention. Thereafter, the above mentioned structure is subjected to an annealing treatment at 400° C. for 10 minutes, thereby alloying the nickel 14, copper 15 and gold 16, and exhibiting an alloyed film 19 with a structure of long-range order superlattice. Next, a p-electrode pad 20 is formed on a portion of the surface of the alloyed film 19.

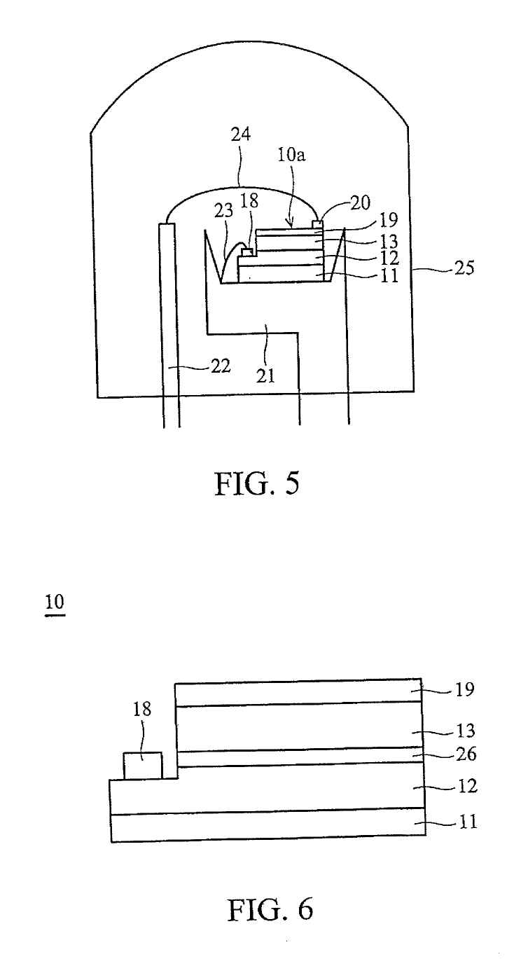

The annealed wafer is cut into chips. Each chip 10a is mounted on a cup-like lead frame 21 as shown in FIG. 5. The p-electrode pad 20 is connected with a separate lead frame 22 by a bonding wire 24, such as a gold wire. The n-electrode pad 18 is connected with the cup-like lead frame 21 through another bonding wire 23, such as a gold wire. Then, the light emitting device is packaged by packaging material 25.

As shown in FIG. 6, in the invention, an active layer 26 is further formed between the n-type semiconductor layer 12 and the p-type semiconductor layer 13 so as to increase the light intensity of the light emitting device.

In the embodiment of the invention, the thickness of the nickel layer is preferably in the range of about 10 Å to 200 Å. The thickness of the copper layer is preferably in the range of about 5 Å to 50 Å. The thickness of the gold layer is preferably in the range of about 50 Å to 150 Å.

In the invention, since the alloyed film has a structure of long-range order superlattice, the alloyed film has superior thermal conductivity. Thus, the alloyed film functions as a heat sink to remove heat from the light emitting device, reducing the temperature.

In the invention, since the alloyed film has a structure of long-range order, the alloyed film has superior electrical conductivity. Thus, the current is uniformly applied to the entire p-type semiconductor layer, and the light emitting device emits uniform light emission. Because of uniform current-distribution in the p-type semiconductor layer, the phenomenon of current gather is disappeared. Moreover, the present invention further increases the ESD value of the light emitting device.

While the preferred embodiment of the present inventior has been described, it is to be understood that modifications will be apparent to those skilled in the art without departing from the spirit of the invention. The scope of the invention, therefore, is to be determined solely by the following claims.

What is claimed is:

1. A light emitting device with uniform light emission, comprising:
a substrate;
an n-type semiconductor layer formed on the substrate;
a p-type semiconductor layer formed on the n-type semiconductor layer;
an n-electrode pad provided in contact with the n-type semiconductor layer; and
an alloyed film formed on the p-type semiconductor layer, wherein the alloyed film has a structure of Long-range order.

2. A light emitting device as claimed in claim 1, wherein the alloyed film is formed by annealing a multi-metal layer.

3. A light emitting device as claimed in claim 2, wherein the multi-metal layer includes nickel and two metals selected from the group consisting of CuAu, CoPt, MgCd, CuPt, TaAu and CuTi.

4. A light emitting device as claimed in claim 1, further comprising an active layer formed between the n-type semiconductor layer and the p-type semiconductor layer.

5. A light emitting device as claimed in claim 1, further comprising a p-electrode pad provided in contact with the alloyed film.

6. A light emitting device as claimed in claim 3, wherein the multi-metal layer further including Ni is annealed at a temperature of 150° C. or more.

7. A light emitting device with uniform light emission, comprising:
a substrate;
an n-type semiconductor layer formed on the substrate;
a p-type semiconductor layer formed on the n-type semiconductor layer;
an n-electrode pad provided in contact with the n-type semiconductor layer; and
an alloyed film of Ni, Cu and Au formed on the p-type semiconductor layer, wherein the alloyed film of Ni, Cu and Au has a structure of long-range order.

8. A light emitting device as claimed in claim 7, wherein the alloyed film of Ni, Cu and Au is formed by annealing a multi-metal layer.

9. A light emitting device as claimed in claim 8, wherein the multi-metal layer sequentially comprises a nickel Layer formed on the p-type semiconductor layer, a copper layer formed on the nickel layer and a gold layer formed on the copper layer.

10. A light emitting device as claimed in claim 9, wherein the multi-metal layer of Ni, Cu and Au is annealed at a temperature of 150° C. or more.

11. A light emitting device as claimed in claim 7, further comprising an active layer formed between the n-type semiconductor layer and the p-type semiconductor layer.

12. A light emitting device as claimed in claim 7, fur-her comprising a p-electrode pad provided in contact with the alloyed film.
